(19) United States
(12) Patent Application Publication
(10) Pub. No.: US 2025/0314692 A1
(43) Pub. Date: Oct. 9, 2025

(54) TESTING APPARATUS AND METHOD FOR OPERATING THE SAME

(71) Applicant: TAIWAN SEMICONDUCTOR MANUFACTURING COMPANY LTD., HSINCHU (TW)

(72) Inventors: CHU-FENG LIAO, HSINCHU COUNTY (TW); SHUO-WEN CHANG, HSINCHU CITY (TW); CHIA WEI HUANG, HSINCHU CITY (TW); HUNG-PING CHENG, CHIAYI CITY (TW); CHIA-YI CHU, HSINCHU (TW); YUAN-YAO CHANG, KAOHSIUNG CITY (TW)

(21) Appl. No.: 18/629,961

(22) Filed: Apr. 9, 2024

(51) Int. Cl. G01R 31/28

(52) U.S. Cl. CPC G01R 31/2844; G01R 31/287

(57) ABSTRACT

The present disclosure provides a testing apparatus, which includes a plurality of devices under test (DUTs) and an advanced process control monitor (APCM). The APCM includes a switch circuit, a control circuit, a detection circuit, and an auxiliary control circuit. The switch circuit includes a plurality of switch devices corresponding to the DUTs. The control circuit includes a plurality of control devices corresponding to the switch devices, and is configured to sequentially activate one of the switch devices during a test procedure of the testing apparatus. The detection circuit is configured to provide a first power supply voltage to a first terminal of each switch device. The auxiliary control circuit is configured to provide a second power supply voltage to a second terminal of each switch device deactivated the control circuit.

### BACKGROUND

The semiconductor integrated circuit (IC) industry has grown rapidly due to advancements in IC materials and design. Each new generation of ICs features smaller and more complex circuits than the previous one. During the fabrication of semiconductor devices, one or more testing processes are typically involved, often utilizing on-chip structures for testing purposes.

### BRIEF DESCRIPTION OF THE DRAWINGS

Aspects of the present disclosure are best understood from the following detailed description when read with the accompanying figures. It is emphasized that, in accordance with standard practice in the industry, various features are not drawn to scale. In fact, the dimensions of the various features can be arbitrarily increased or reduced for clarity of discussion.

FIG. 1 is a block diagram of a testing apparatus in accordance with some embodiments of the present disclosure.

FIG. 2 is a diagram illustrating connection between the DUTs, switch circuit, and control circuit in the testing apparatus in FIG. 1.

FIG. 3A is a schematic diagram of the switching circuit in accordance with some embodiments of the present disclosure.

FIG. 3B is a schematic diagram of the control circuit in accordance with some embodiments of the present disclosure.

FIG. 3C is a waveform diagram of various signals within the control circuit in accordance with some embodiment of the present disclosure.

FIG. 3D is another schematic diagram of the control circuit in accordance with some embodiments of the present disclosure.

FIG. 3E is yet another schematic diagram of the control circuit in accordance with some embodiments of the present disclosure.

FIG. 4A is a cross section of the deactivated first switch S1 in the switch device in accordance with some embodiments of the present disclosure.

FIG. 4B is another cross section of the deactivated first switch S1 in the switch device in accordance with some embodiments of the present disclosure.

FIG. 4C is a cross section of the activated first switch S1 in the switch device in accordance with some embodiments of the present disclosure.

FIG. 5A is a part of a schematic diagram of the switch circuit in accordance with some embodiments of the present disclosure.

FIG. 5B is a schematic diagram of the control circuit in accordance with some embodiments of the present disclosure.

FIG. 5C is a waveform diagram of various signals in the switch circuit in FIG. 5A.

FIG. 6 is a flowchart of a method for operating a testing apparatus in accordance with some embodiments of the present disclosure.

FIG. 7 is another flowchart of a method for operating a testing apparatus in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features can be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “upper,” “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, it will be understood that when an element is referred to as being “connected to” or “coupled to” another element, it can be directly connected to or coupled to the other element, or intervening elements can be present.

Embodiments, or examples, illustrated in the drawings are disclosed as follows using specific language. It will nevertheless be understood that the embodiments and examples are not intended to be limiting. Any alterations or modifications in the disclosed embodiments, and any further applications of the principles disclosed in this document are contemplated as would normally occur to one of ordinary skill in the pertinent art.

Further, it is understood that several processing steps and/or features of a device can be only briefly described. Also, additional processing steps and/or features can be added, and certain of the following processing steps and/or features can be removed or changed while still implementing the claims. Thus, it is understood that the following descriptions represent examples only, and are not intended to suggest that one or more steps or features are required.

In addition, the present disclosure may repeat reference numerals and/or letters in the various examples. This repetition is for the purpose of simplicity and clarity and does not in itself dictate a relationship between the various embodiments and/or configurations discussed.

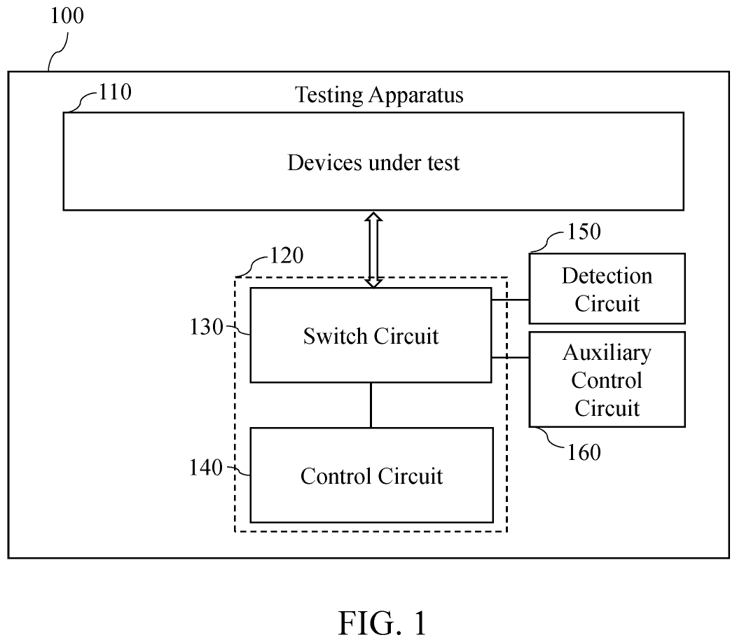

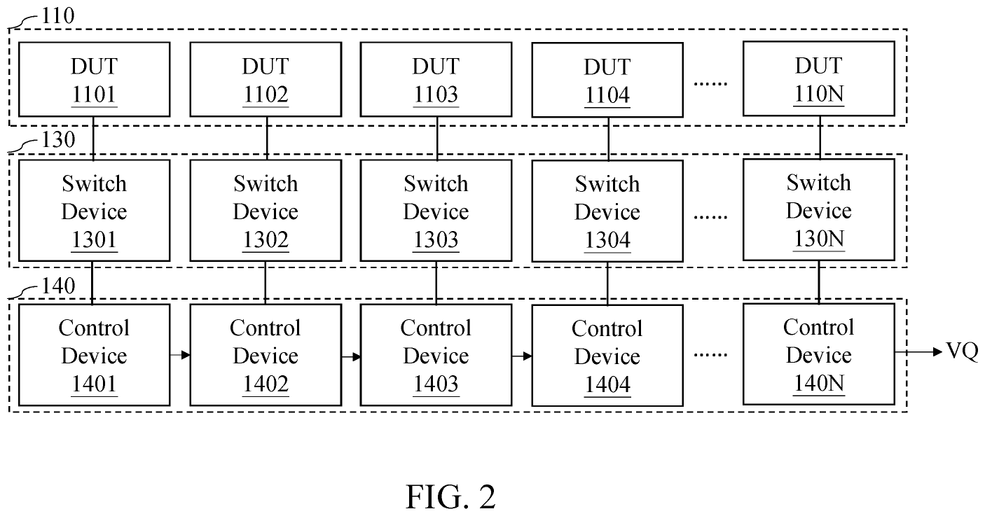

FIG. 1 is a block diagram of a testing apparatus in accordance with some embodiments of the present disclosure. FIG. 2 is a diagram illustrating connection between the DUTs, switch circuit, and control circuit in the testing apparatus in FIG. 1.

In some embodiments, the testing apparatus 100 may include a plurality of devices under test (DUTs) 110, a switch circuit 130, a control circuit 140, a detection circuit 150, and an auxiliary control circuit 160. The switch circuit 130 and the control circuit 140 can be collectively referred to as an advanced process control monitor (APCM) 120. In some embodiments, APCM 120 can also be referred to as a process control monitor (PCM) or DUT selection circuitry.

Referring to FIG. 2, in some embodiments, the DUTs 110 may include DUTs 1101 to 110N, that are circuits in different types that are designed for testing semiconductor circuits or components fabricated on a semiconductor wafer. The switch circuit 130 may include a plurality of switch devices (e.g., switch devices 1301 to 130N shown in FIG. 2) that can be selectively activated and deactivated (e.g., turned on and off, or closed and opened). A first terminal of each switch device is coupled to a respective one of the terminals of the DUTs 110. The switch circuit 130 is electrically coupled to and controlled by the control circuit 140. The control circuit 140 may include a plurality of control devices (e.g., control devices 1401 to 140N shown in FIG. 2) configured to selectively activate the switch devices. In some embodiments, the control circuit 140 may include a plurality of flip-flops as the control devices. In an embodiments, the flip-flops includes, but not limited to D flip-flops. In some embodiments, the flip-flops in the control circuit 140 may form a shift register. When a voltage pulse is applied to the control circuit 140, the voltage pulse may pass through the control devices 1401 to 140N (e.g., flip-flops) one by one every clock cycle, allowing the control circuit 140 to activate the switch devices one by one, as shown in FIG. 2. Specific details of the control circuit 140 will be described later.

In some embodiments, the detection circuit 150 may be configured to provide a first power supply voltage (e.g., VDD1) to a second terminal of each switch device of the switch circuit 130, and to detect a respective current (e.g., IDE) induced by each DUT 110 through the respective activated switch device.

In some embodiments, the auxiliary control circuit 160 may be configured to selectively provide a second power supply voltage (e.g., VDD2) to the first terminal of each deactivated switch device in the switch circuit 130 based on the selection signal from the respective control device corresponding to each switch device. In some embodiments, the first power supply voltage may be substantially equal to the second power supply voltage. In some embodiments, the first power supply voltage and the second power supply voltage may be slightly different due to process variations of the switch devices and the distance of routing paths. More specifically, the second power supply voltage provided by the auxiliary control circuit 160 may be designed to eliminate the voltage difference between the first terminal and second terminal of the deactivated switch device. In some embodiments, the first switch S1 and second switch S2 of the switch devices 1301 to 130N can be implemented using P-type transistors, thereby reducing the leakage current of the switch devices being deactivated.

In some embodiments, the auxiliary control circuit 160 can be integrated into the detection circuit 150 (not explicitly shown in the figures). Thus, the detection circuit 150 can further be configured to provide a first power supply voltage (e.g., VDD1) to a first terminal of each switch device, and to selectively provide a second power supply voltage (e.g., VDD2) to a second terminal of each switch device deactivated by the control circuit 140 based on a selection signal from the control device (e.g., one of the control devices 1401 to 140N) corresponding to each switch device.

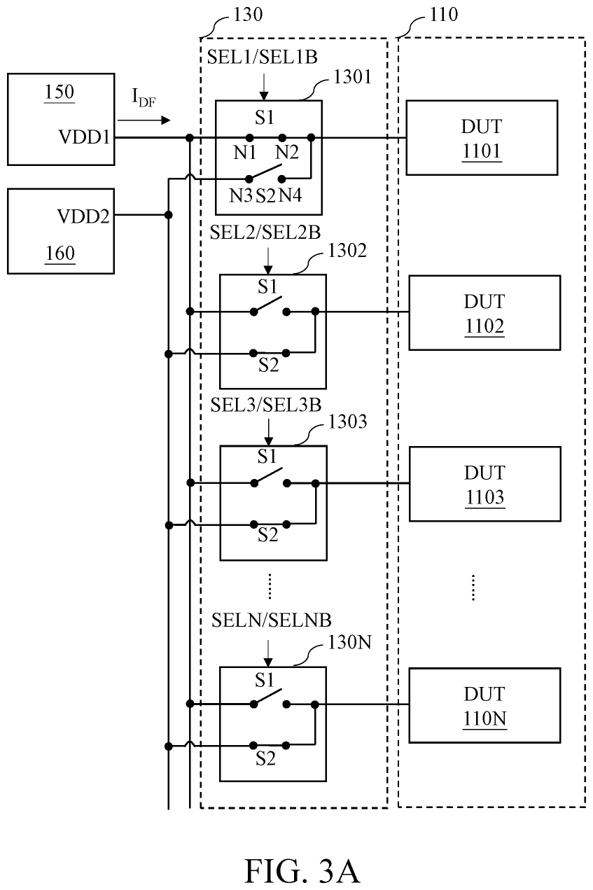

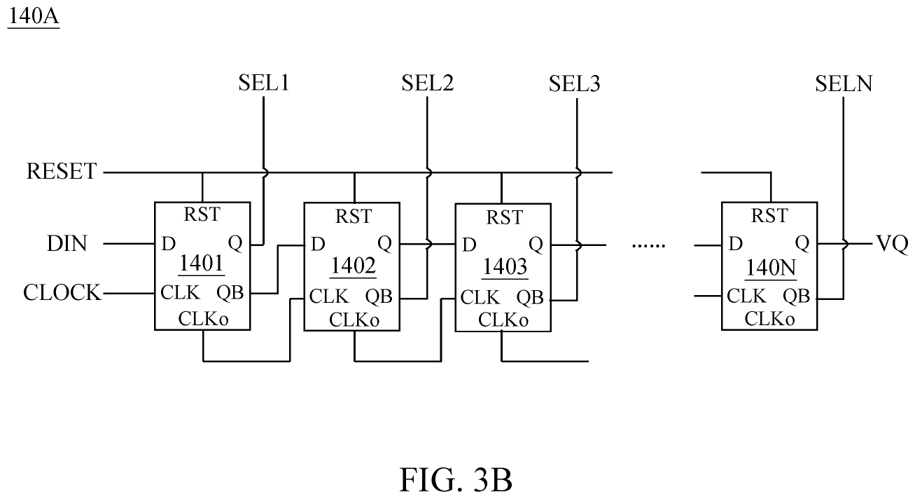

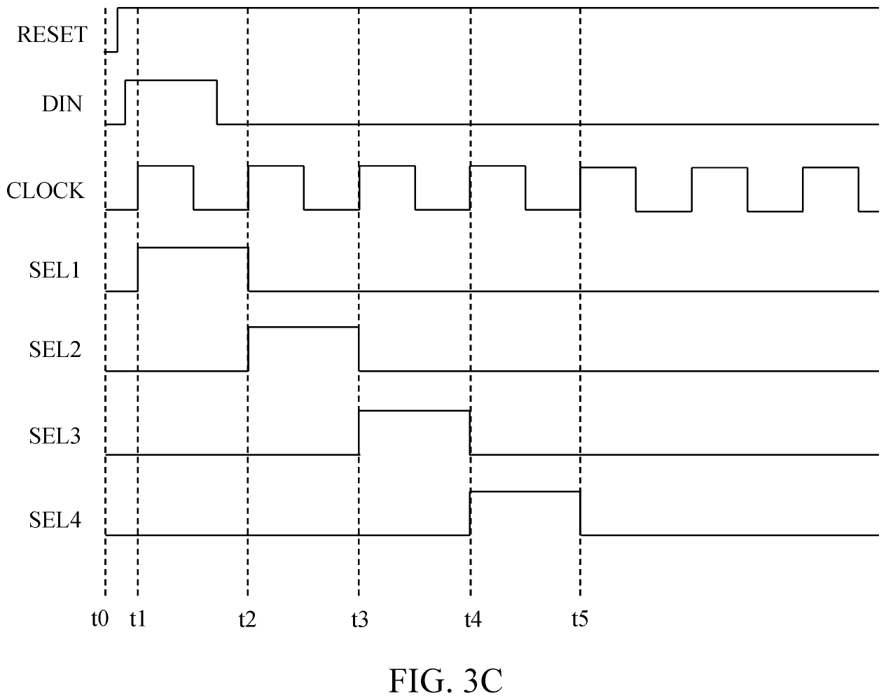

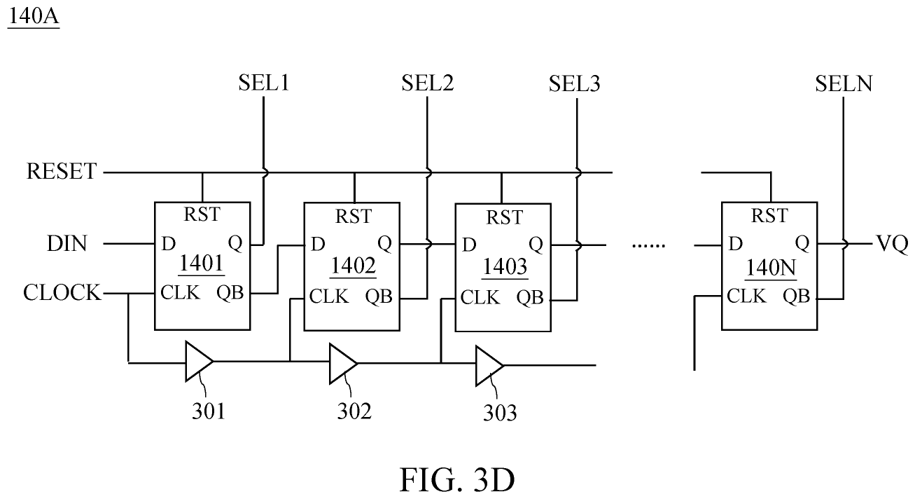

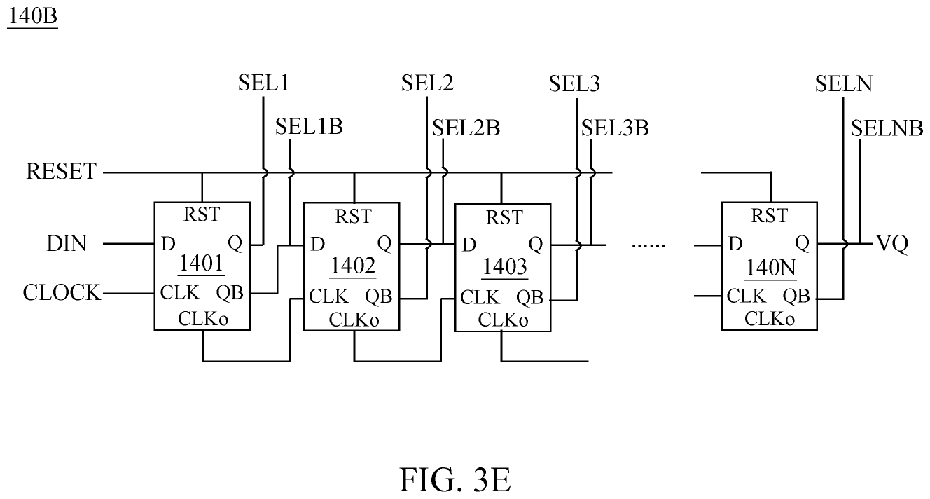

FIG. 3A is a schematic diagram of the switching circuit in accordance with some embodiments of the present disclosure.

As depicted in FIG. 3A, in some embodiments, each of the switch devices 1301 to 130N includes a first switch S1 and a second switch S2. For example, the first switch S1 and the second S2 of the switch device 1301 may be controlled by the selection signals SEL1 and SEL1B (e.g., complementary to SEL1), respectively. The first switch S1 and the second switch S2 of the switch device 1302 may be controlled by the selection signals SEL2 and SEL2B, respectively, and so on. In some embodiments, the selection signals SEL1 to SELN and SEL1B to SELNB may be generated by the control circuit 140. In some embodiments, the selection signals SEL1 to SELN may be generated by the control circuit 140, and the selection signals SEL1B and SELNB may be generated by the auxiliary control circuit 160.

In some embodiments, a first terminal (e.g., node N1) and a second terminal (e.g., node N2) of the first switch S1 in each of the switch devices 1301 to 130N may be coupled to the detection circuit 150 and the corresponding DUT (e.g., one of the DUTs 1101 to 110N), respectively. Additionally, a first terminal (e.g., node N3) and a second terminal (e.g., node N4) of the second switch S2 in each of the switch devices 1301 to 130N may be coupled to the auxiliary control circuit 160 and the second terminal (e.g., node N2) of the first switch S1.

In some embodiments, for each of the switch devices 1301 to 130N, one of the first switch S1 and second switch S2 is activated (i.e., turned on or closed). Referring to the switch device 1301, the selection signals SEL1 and SEL1B are complementary. When the first switch S1 is activated based on the selection signal SEL1 (e.g., logic 1), the second switch S2 is deactivated based on the selection signal SEL1B (e.g., logic 0). Similarly, when the first switch S1 is deactivated based on the selection signal SEL1 (e.g., logic 0), the second switch S2 is activated based on the selection signal (e.g., logic 1). The first switch S1 and the second switch S2 in other switch devices 1302 to 130N can operate in a similar manner.

In some embodiments, the first switch S1 and the second S2 of the switch device 1301 may be controlled by the selection signals SEL1B and SEL1, respectively. The first switch S1 and the second S2 of the switch device 1302 may be controlled by the selection signals SEL2B and SEL2, respectively, and so on. When the first switch S1 is activated based on the selection signal SEL1B (e.g., logic 1), the second switch S2 is deactivated based on the selection signal SEL1 (e.g., logic 0). Similarly, when the first switch S1 is deactivated based on the selection signal SEL1B (e.g., logic 0), the second switch S2 is activated based on the selection signal SEL1 (e.g., logic 1).

FIG. 3B is a schematic diagram of the control circuit in accordance with some embodiments of the present disclosure. FIG. 3C is a waveform diagram of various signals within the control circuit in FIG. 3B.

The control circuit 140 shown in FIG. 1 may also be implemented using the control circuit 140A shown in FIG. 3B. In some embodiments, the control circuit 140A may include a plurality of control devices 1401 to 140N (i.e., N control devices), and each of the control devices 1401 to 140N can be implemented using a D flip-flop. Each of the control devices 1401 to 140N can store a logic state, such as logic 1 or logic 0. For example, each of the control devices 1401 to 140N may have a data input terminal D, a reset terminal RST, a clock input terminal CLK, a data output terminal Q, an inverse data output terminal QB, and a clock output terminal CLKo. For example, the output (Q) of the control device 1401 is the selection signal SEL1, and the inverse outputs (QB) of the control device 1402 to 140N are the selection signals SEL2 to SELN, respectively. Additionally, the selection signals SEL1 to SELN are provided to the switch devices 1301 to 130N to control the corresponding first switch S1, respectively.

In some embodiments, the data input terminal D of the control device 1401 may receive an input data signal DIN, and the clock input terminal CLK may receive a clock signal CLOCK. The output signal at the data output terminal Q of the control device 1401 may serve as the selection signal SEL1. Additionally, the output signal at the inverse data output terminal QB of the control device 1401 may be provided to the data input terminal D of the control device 1402, and the output clock signal at the clock output terminal CLKo of the control device 1401 may be provided to the clock input terminal CLK of the control device 1402. Similarly, the output signal at the data output terminal Q of the control device 1402 may be provided to the data input terminal D of the control device 1403, and the output signal at the inverse data output terminal QB of the control 1402 may serve as the selection signal SEL2, and so on. It should be noted that the output signal at the data output terminal Q of the N-th control device 140N may serve as the voltage signal VQ which can be used to report that the test procedure of the DUTs 1101 to 110N is successfully completed. Additionally, the reset terminals of the control devices 1401 to 140N may be electrically connected to a reset signal RESET for a global reset operation.

In some embodiments, each of the switch devices 1301 to 130N may include an inverter to convert the received selection signal (e.g., SELN or SELNB) to an inverse selection signal, so the selection signal and the inverse selection signal can be used to control the first switch S1 and the second switch S2 (or vice versa), respectively.

Referring to FIG. 3C, in some embodiments, upon initialization of the ACPM 120, the control devices 1401 to 140N may be reset by a reset signal RESET in a low logic state (e.g., logic 0). At this time, the data output terminal Q and inverse data output terminal QB of each of the control devices 1401 are reset to 0 and 1, respectively. After de-assertion of the reset signal RESET (e.g., logic 1), the input data signal DIN, which may be a voltage pulse shorter than a clock cycle, is provided to the data input terminal D of the control device 1401. At time t1, at the rising edge of the clock signal CLOCK, the high logic state of the input data signal DIN is latched by the control device 1401, and the output signals at the data output terminal Q and the inverse data output terminal QB of the control device 1401 are in the high logic state and the low logic state, respectively. Accordingly, the output signal (e.g., SEL1) at the data output terminal Q of the control device 1401 can be used to activate the switch device 1301 within the interval from time t1 to t2, as shown in FIG. 3A.

At time t2, at the rising edge of the clock signal CLOCK, the low logic state at the inverse output terminal QB is latched by the control device 1402. The output signals at the output terminal Q and the inverse output terminal QB of the control device 1402 may be in the low logic state (e.g., logic 0) and the high logic state (e.g., logic 1), respectively. Accordingly, the output signal (e.g., SEL2) at the inverse data output terminal QB of the control device 1402 can be used to activate the switch device 1302 within the interval from time t2 to t3.

At time t3, at the rising edge of the clock signal CLOCK, the low logic state at the inverse output terminal QB is latched by the control device 1403. The output signals at the output terminal Q and the inverse output terminal QB of the control device 1403 may be in the low logic state (e.g., logic 0) and the high logic state (e.g., logic 1), respectively. Accordingly, the output signal (e.g., SEL3) at the inverse data output terminal QB of the control device 1403 can be used to activate the switch device 1303 within the interval from time t3 to t4.

At time t4, at the rising edge of the clock signal CLOCK, the low logic state at the inverse output terminal QB is latched by the control device 1404. The output signals at the output terminal Q and the inverse output terminal QB of the control device 1404 may be in the low logic state (e.g., logic 0) and the high logic state (e.g., logic 1), respectively. Accordingly, the output signal (e.g., SEL4) at the inverse data output terminal QB of the control device 1404 can be used to activate the switch device 1304 within the interval from time t4 to t5. Additionally, the remaining control devices 1405 to 140N in the control circuit 140 can operate in a similar manner, allowing the control devices 1405 to 140N to activate the switch devices 1305 to 130N one by one every clock cycle.

FIG. 3D is another schematic diagram of the control circuit in accordance with some embodiments of the present disclosure.

The control circuit 140 shown in FIG. 1 may also be implemented using the control circuit 140B shown in FIG. 3D. The control circuit 140B shown in FIG. 3D may be similar to the control circuit 140 shown in FIG. 3B, with the difference being that the clock output terminals of the control device 1401 to 140N can be omitted, and the clock input terminals of the control device 1401 to 140N can be connected to the clock signal CLOCK. In some embodiments, one or more clock buffers (e.g., clock buffers 301, 302, 303, etc.) may be inserted between the clock routing path from the control device 1401 to the control device 140N, as shown in FIG. 3D, thereby ensuring the quality of the clock signal received by each of the control devices 1401 to 140N.

FIG. 3E is yet another schematic diagram of the control circuit in accordance with some embodiments of the present disclosure.

The control circuit 140 shown in FIG. 1 may also be implemented using the control circuit 140B shown in FIG. 3E. The control circuit 140C shown in FIG. 3E may be similar to the control circuit 140A shown in FIG. 3B, with the difference being that each of the control devices 1401 to 140N in FIG. 3E can provide two selection signals that are complementary to each other. For example, the output signals at the data output terminal Q and the inverse data output terminal QB of the control device 1401 may be used as the selection signals SEL1 and SEL1B, respectively. Additionally, the output signals at the data output terminal Q and the inverse data output terminal QB of the control device 1401 may be used as the selection signals SEL2B and SEL2, respectively, and so on. Specifically, the first switch S1 and the second switch S2 in each of the switch devices 1301 to 130N can be controlled by the selection signals SELN and SELNB (or vice versa), respectively, where N denotes on the respective number of each switch device.

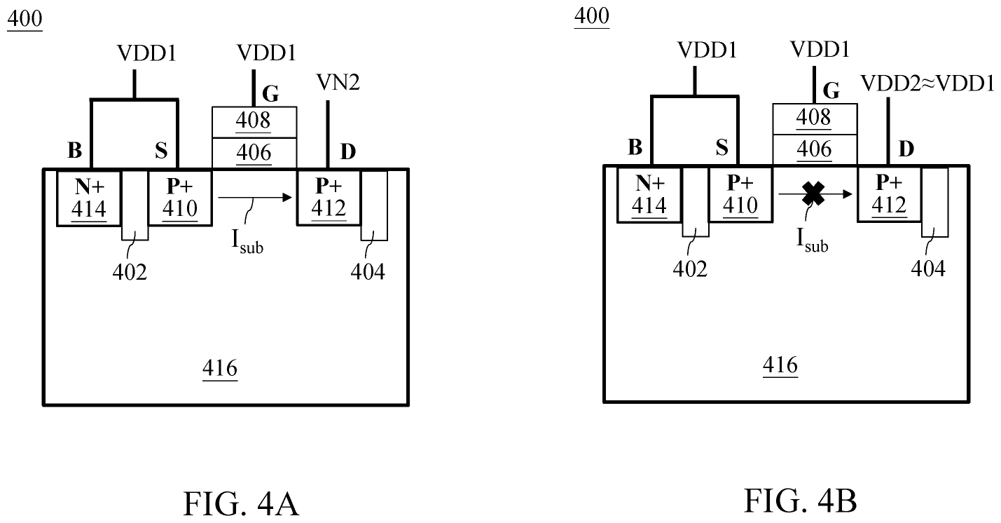

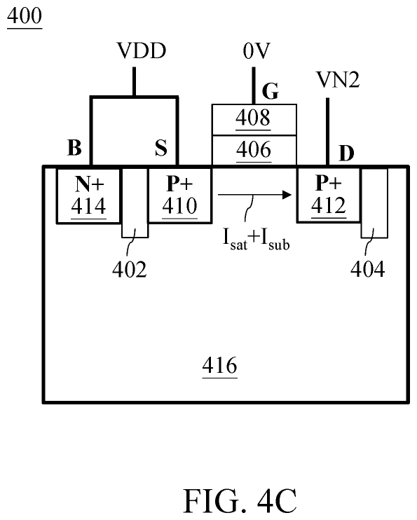

FIG. 4A is a cross section of the deactivated first switch S1 in the switch device in accordance with some embodiments of the present disclosure. Please refer to FIG. 3A and FIG. 4A.

In some embodiments, the switch S1 of each of the switch device 1301 to 130N may be implemented using transistor 400 shown in FIG. 4A. Transistor 400 may include a substrate 416, well regions 410, 412, and 414, a gate dielectric 406, a gate electrode 408, and shallow trench isolation (STI) regions 402 and 404. The substrate 416 may be or include a semiconductor wafer such as a silicon wafer. Alternatively, the substrate 416 may include other elementary semiconductors such as germanium. The substrate 416 may also include a compound semiconductor such as silicon carbide, gallium arsenic, indium arsenide, or indium phosphide. The substrate 416 may include an alloy semiconductor such as silicon germanium, silicon germanium carbide, gallium arsenic phosphide, or gallium indium phosphide. In some embodiments, the substrate 416 includes an N-type silicon wafer, which may be regarded as an N-type substrate. Alternatively, the substrate 416 may be an N-type well region that is formed on a P-type substrate.

In some embodiments, the well regions 410 and 412 may be a P-type well region. The well region 414 may be an N-type well region. The well region 410 may be regarded as a source terminal of transistor 400, and the well region 414 may be regarded as a bulk (or body) terminal of transistor 400. The well regions 410 and 414 are separated by the STI region 402. Transistor 400 may include a gate structure disposed on the substrate 416, and the gate structure may include a gate dielectric 406 and a gate electrode 408 disposed on the gate dielectric 406. The gate dielectric 406 includes a silicon dioxide layer formed by thermal oxidation, chemical vapor deposition (CVD), physical vapor deposition (PVD), atomic layer deposition (ALD), or other suitable processes, or combinations thereof. Alternatively, the gate dielectric 406 may include high dielectric-constant (high-k) materials, silicon oxynitride, other suitable materials, or combinations thereof. The gate dielectric 406 may be multilayered of, for example, silicon oxide and high-k material.

The gate electrode 408 may be designed to be coupled to metal interconnects and disposed overlying the gate dielectric 406. The gate electrode 408 may include doped polycrystalline silicon (or polysilicon). Alternatively, the gate electrode 408 may include a metal such as Al, Cu, W, Ti, Ta, TiN, TaN, NiSi, CoSi, other suitable conductive materials, or combinations thereof. The gate electrode 408 may be formed by CVD, PVD, plating, and other acceptable processes. The gate electrode 408 may be multilayered and formed by a multi-step process.

In some embodiments, the well region 414 (e.g., bulk terminal) may be a highly doped N-type implanted region (e.g., N+), and the well regions 410 and 412 (e.g., source terminal and drain terminal) may be highly doped P-type implanted region (e.g., P+). In addition, another STI region 404 may be formed next to the well region 412.

In the configuration shown in FIG. 4A, the source terminal 410 and bulk terminal 414 are electrically connected to the power supply voltage VDD1, the drain terminal 412 is connected to the voltage VN2 at node N2 (shown in FIG. 3A), and the gate electrode 408 is electrically connected to a selection signal (e.g., SEL1B). The voltage VN2 may range from 0V to the first power supply voltage VDD1. When the selection signal SEL1 is in the low logic state (e.g., logic 0), the selection signal SEL1B is in the high logic state (e.g., logic 1), and thus the first power supply voltage VDD1 is provided to the gate electrode 408. Accordingly, transistor 400 is deactivated (i.e., turn-off state).

It should be noted that although transistor 400 is deactivated, a leakage current called as a subthreshold current I_{sub}, which is from the source terminal 410 to the drain terminal 412 shown in FIG. 4A, still exists since there is a voltage difference between the source terminal 410 (e.g., supplied with VDD1) and the drain terminal 412 (e.g., supplied with VN2). When the configuration shown in FIG. 4A is used for the first switch S1 of the switch devices 1301 to 130N, the overall leakage current of the switch circuit 130 can be considerable since one of the switch devices 1301 to 130N is activated at one time during the test procedure.

FIG. 4B is another cross section of the deactivated first switch S1 in the switch device in accordance with some embodiments of the present disclosure.

The configuration of transistor 400 shown in FIG. 4B may be similar to that shown in FIG. 4A, with the difference being that the drain terminal 412 of transistor 400 in FIG. 4B is electrically connected to the second power supply voltage VDD2 (e.g., from the auxiliary control circuit 160), wherein the second power supply voltage VDD2 is substantially equal to the first power supply voltage VDD1. Since the voltage difference between the source terminal 410 and the drain terminal 412 is substantially equal to 0, the subthreshold current I_{sub} from the source terminal 410 to the drain terminal 412 can be eliminated.

FIG. 4C is a cross section of the activated first switch S1 in the switch device in accordance with some embodiments of the present disclosure.

As depicted in FIG. 4C, the source terminal 410 and bulk terminal 414 are electrically connected to the power supply voltage VDD1, the drain terminal 412 is connected to the voltage VN2 at node N2 (shown in FIG. 3A), and the gate electrode 408 is electrically connected to a selection signal (e.g., SEL1B) in the low logic state (e.g., 0V). Accordingly, transistor 400 is activated (e.g., in a turn-on state or operates a saturation region), and a conductive current (e.g., a saturation current) Iₛₐₜ flows from the source terminal 410 to the drain terminal 412. It should be noted that both the conductive current Iₛₐₜ and the subthreshold current I_{sub} are from the source terminal 410 to the drain terminal 412 when transistor 400 is activated.

Specifically, referring to FIG. 3A, for the switch device 1301, the first switch S1 is activated, and the second switch S2 is deactivated, resulting in a conductive current (e.g., Iₛₐₜ shown in FIG. 4C) flowing through the first switch S1 (e.g., from the source terminal to the drain terminal or vice versa). Since the second switch S2 is deactivated, the second power supply voltage VDD2 is not provided to the drain terminal (e.g., node N2) of the first switch, the subthreshold current of the first switch S1 exists. However, the subthreshold current can be neglected since it is relatively smaller than the saturation current Iₛₐₜ of the first switch S1 (e.g., transistor 400 shown in FIG. 4C). For each of the switch devices 1302 to 130N, the second power supply voltage VDD2 is provided to the second terminal close to the respective DUT (e.g., 1102 to 110N), thereby eliminating the subthreshold current I_{sub} of the first switch S1 in each of the switch devices 1302 to 130N. Therefore, the overall leakage current of the switching circuit 130 can be significantly reduced. In some embodiments, the second switch S2 of each of the switch device 1301 to 130N may be implemented using transistor 400 shown in FIG. 4A, and thus the details thereof will not be repeated here.

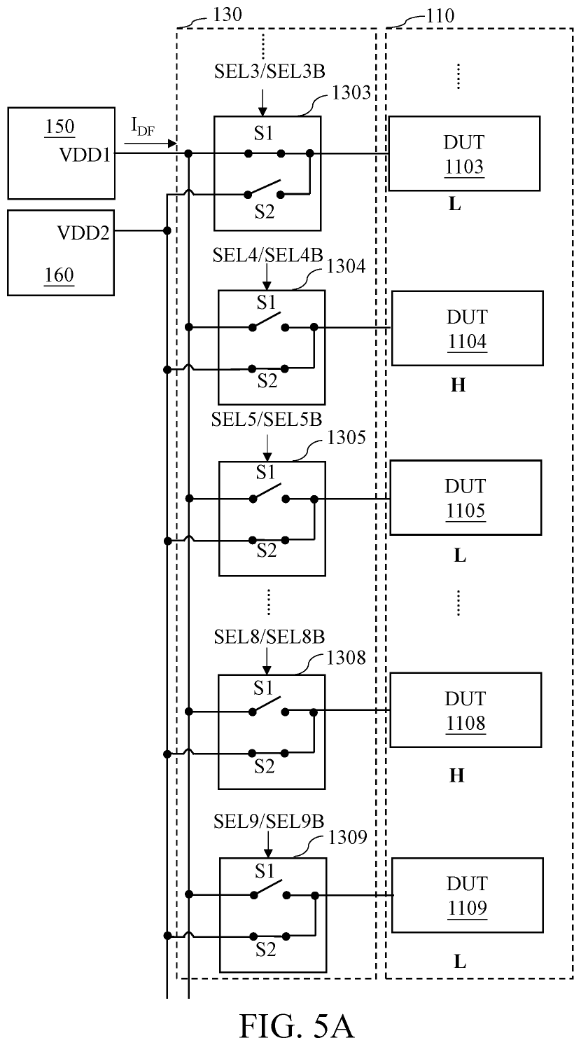

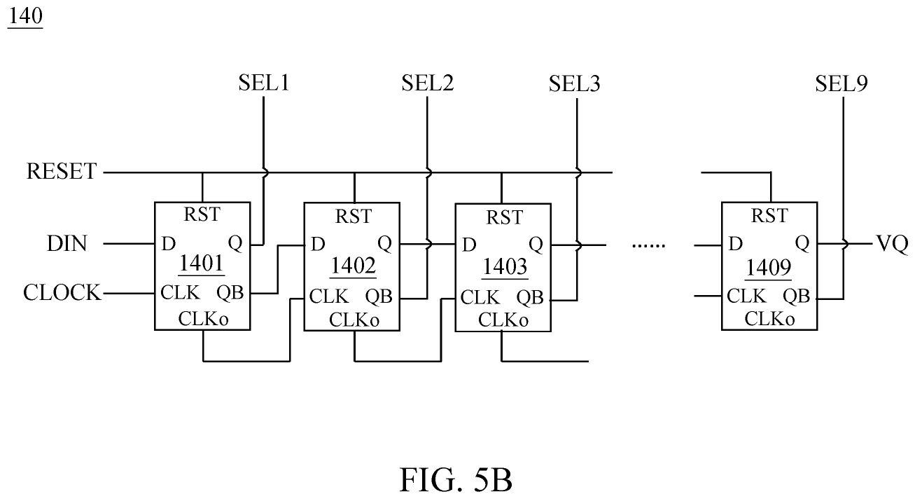

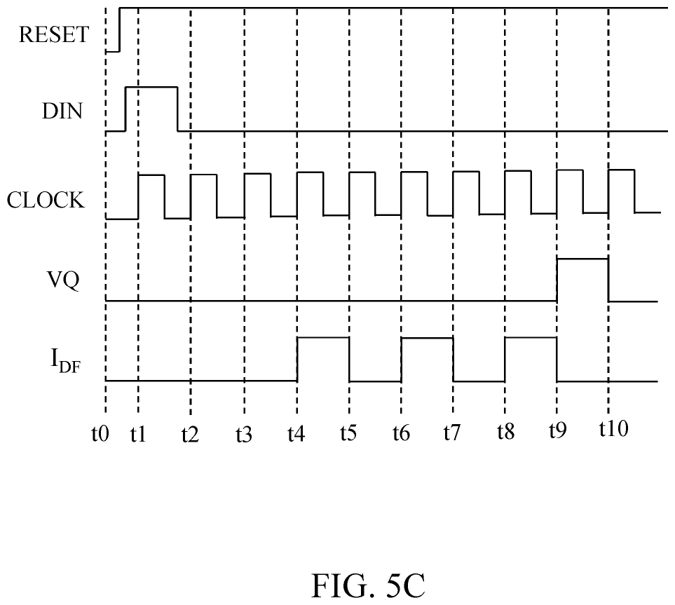

FIG. 5A is a part of a schematic diagram of the switch circuit in accordance with some embodiments of the present disclosure. FIG. 5B is a schematic diagram of the control circuit in accordance with some embodiments of the present disclosure. FIG. 5C is a waveform diagram of various signals in the switch circuit in FIG. 5A.

For simplicity, in the embodiment of FIG. 5A, the switch circuit 130 includes switch devices 1301 to 1309, and the DUTs 110 includes DUT 1101 to 1109 (i.e., N=9). In some embodiments, the detection circuit 150 can detect the current I_{DF} of each DUT (e.g., DUT 1101 to 1109) with the respective switch device (e.g., switch device 1301 to 1309) being activated during the testing procedure of the testing apparatus 100. The current I_{DF} for each common DUT, such as DUTs 1101 and 1102, may vary. The DUTs 1103 to 1109 (e.g., 7 DUTs) may be designed as dummy devices providing a particular feature pattern, allowing the operator to check whether the testing apparatus 100 operates normally based on the particular feature pattern. In some embodiments, each of the DUTs 1103 to 1109 may be a transistor providing a particularly designed current. Here, it is assumed that L and H denote a low current and a high current, respectively. Additionally, the statuses of the currents generated by the DUTs 1103 to 1109 may be L, H, L, H, L, H, and L, respectively.

Referring to FIG. 5C, after the reset signal RESET is de-asserted (e.g., logic 1), the test procedure of the testing apparatus 100 starts. At time t1, the control device 1401 latches the input data signal DIN at the rising edge of the clock signal CLOCK. The behavior of the delay chain formed by the control devices 1401 to 1409 shown in FIG. 5B can be referred to the embodiment of FIGS. 3B and 3C, and thus the details will not be repeated here. At time t3, the switch device 1303 is activated (e.g., the first switch is turned on and the second switch is turned off), and the detection circuit 150 may detect a low current I_{DF} (i.e., L) from time t3. At time t4, the switch device 1304 is activated, and the detection circuit 150 may detect a high current I_{DF} (i.e., H) from time t4. Similarly, the status of the current I_{DF} detected by the detection circuit 150 at times t5, 16, 17, 18, and t9 may be L, H, L, H, and L, respectively. Specifically, the test procedure of the testing apparatus 100 starts, the detection circuit 150 detects a particular feature pattern (e.g., a pattern of the current I_{DF}) as L, H, L, H, L, H, L within a period of 7 clock cycles (e.g., time t3 to t10), including the clock cycle within which the voltage signal VQ being asserted (e.g., logic 1). It should be noted that the particular feature pattern is not limited to the aforementioned pattern, and the number of dummy devices can be adjusted according to practical needs.

In some embodiments, incidents may occur in the testing apparatus 100 that prevent the control circuit 140 from reporting the voltage signal VQ normally. In such situations, the operator of the testing apparatus 100 can assess the normal functioning of the testing apparatus 100 by observing whether the testing apparatus 100 can generate the particular feature pattern (e.g., a pattern of the current I_{DF}). Therefore, the operator can assess the normal functioning of the testing apparatus 100 by either the reported voltage signal VQ or the particular feature pattern, thereby improving the reliability of the testing apparatus 100 and the efficiency of the test procedure.

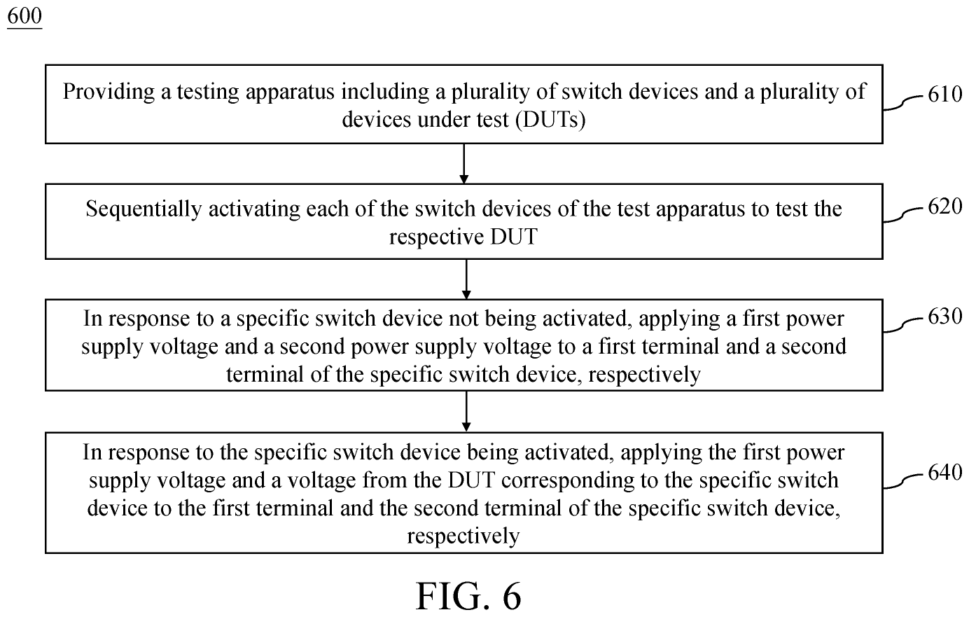

FIG. 6 is a flowchart of a method for operating a testing apparatus in accordance with some embodiments of the present disclosure. Please refer to FIGS. 1, 2, and 6.

At operation 610, a testing apparatus (e.g., testing apparatus 100 shown in FIG. 1) including a plurality of switch devices (e.g., switch devices 1301 to 130N of the switch circuit 130 shown in FIG. 3) and a plurality of devices under test (DUTs) is provided.

At operation 620, each of the switch devices of the testing apparatus is sequentially activated to test the respective DUT. For example, activation of the switch devices 1301 to 130N may be controlled by the respective control devices 1401 to 140N of the control circuit 140. The particular feature (e.g., an induced current IDE) of each DUT can be detected when the respective switch circuit of each DUT is activated.

At operation 630, in response to a specific switch device not being activated, a first power supply voltage (e.g., VDD1) and a second power supply voltage (e.g., VDD2) is applied to a first terminal and a second terminal of the specific switch circuit. In some embodiments, the first power supply voltage VDD1 is substantially equal to the second power supply voltage VDD2. In some embodiments, the second power supply voltage VDD2 provided by the auxiliary control circuit 160 may be higher than the first power supply voltage VDD1 so as to compensate the voltage drop caused by the routing path from the auxiliary control circuit to the specific switch device. In some embodiments, each of the switch circuit may be implemented using a P-type transistor, such as transistor 400 shown in FIGS. 4A-4C. When transistor 400 is turned off, substantially the same power supply voltages can be applied to the source terminal and drain terminal of transistor 400, thereby eliminating the subthreshold current I_{sub} from the source terminal and the drain terminal of transistor 400.

At operation 640, in response to the specific switch circuit being activated, the power supply voltage and a voltage from the DUT corresponding to the specific switch device are applied to the first terminal and the second terminal of the specific switch device, respectively. In some embodiments, when the specific switch circuit (e.g., a P-type transistor) is activated, a conductive current (e.g., a saturation current Iₛₐₜ) may flow from the source terminal to the drain terminal. At this time, the subthreshold current I_{sub} from the source terminal to the drain terminal still exists, but can be neglected since it is relatively smaller than the saturation current Iₛₐₜ.

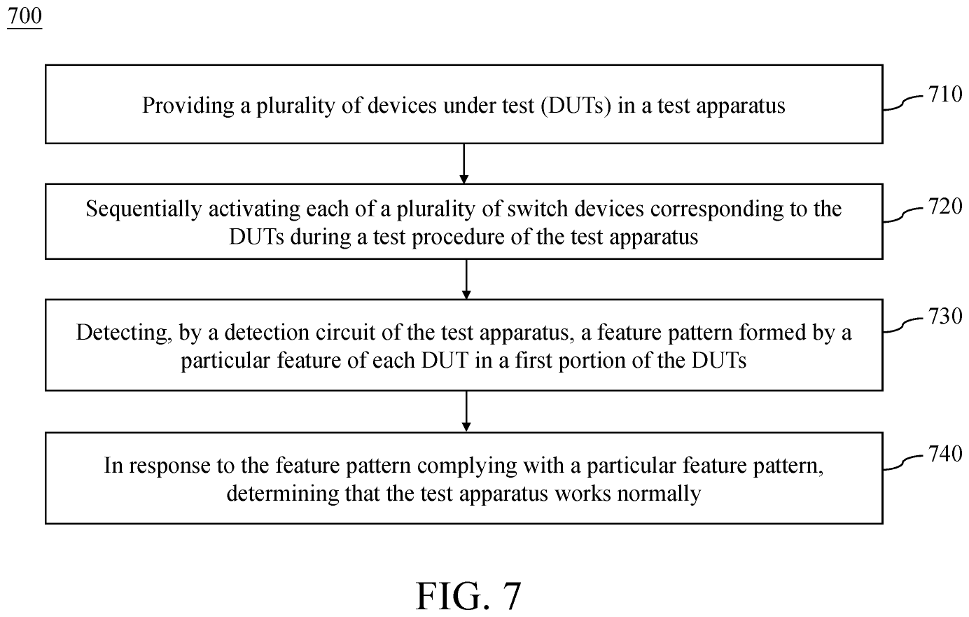

FIG. 7 is another flowchart of a method for operating a testing apparatus in accordance with some embodiments of the present disclosure. Please refer to FIG. 1, FIG. 5A, and FIG. 5C.

At operation 710, a plurality of devices under test (DUTs) in a testing apparatus is provided.

At operation 720, each of a plurality of switch devices corresponding to the DUTs are sequentially activated during a test procedure of the testing apparatus. For example, activation of the switch devices 1301 to 130N may be controlled by the respective control devices 1401 to 140N of the control circuit 140. The particular feature (e.g., an induced current I_{DF}) of each DUT can be detected when the respective switch circuit of each DUT is activated.

At operation 730, a feature pattern formed by a particular feature of each DUT in a first portion of the DUTs is detected by a detection circuit of the testing apparatus. For example, the first portion of the DUTs may be dummy devices (e.g., DUTs 1103 to 1109 in FIG. 5A) that are appended to the normal DUTs in the testing apparatus 100, and each of the dummy devices may have a particular feature (e.g., generating a low current or a high current). The detection circuit 150 can detect the feature pattern formed by the particular feature of each DUT in the first portion.

At operation 740, in response to the feature pattern complying with a particular feature pattern, it is determined that the testing apparatus works normally. For example, the feature pattern of each DUT in the first portion can be particularly designed, such as the L, H, L, H, L, H, L pattern of the current I_{DF} shown in FIGS. 5A and 5C. If the feature pattern detected by the detection circuit 150 complies with the particular feature pattern, it is determined that the testing apparatus works normally. It should be noted that the particular feature pattern is not limited to the aforementioned pattern, and the number of dummy devices can be adjusted according to practical needs.

An aspect of the present disclosure provides a testing apparatus, which includes a plurality of devices under test (DUTs) and an advanced process control monitor (APCM). The APCM includes a switch circuit, a control circuit, a detection circuit, and an auxiliary control circuit. The switch circuit includes a plurality of switch devices corresponding to the DUTs. The control circuit includes a plurality of control devices corresponding to the switch devices, and is configured to sequentially activate one of the switch devices during a test procedure of the testing apparatus. The detection circuit is configured to provide a first power supply voltage to a first terminal of each switch device. The auxiliary control circuit is configured to provide a second power supply voltage to a second terminal of each switch device deactivated by the control circuit.

Another aspect of the present disclosure provides a method, which includes the following steps: providing a testing apparatus including a plurality of switch devices and a plurality of devices under test (DUTs); sequentially activating each of the switch devices of the testing apparatus to test the respective DUT; and in response to a specific switch device not being activated, applying a first power supply voltage and a second power supply voltage to a first terminal and a second terminal of the specific switch device, respectively.

Yet another aspect of the present disclosure provides a testing apparatus, which includes a plurality of devices under test (DUTs) and an advanced process control monitor (APCM). The APCM includes a switch circuit, a control circuit, and a detection circuit. The switch circuit includes a plurality of switch devices corresponding to the DUTs. The control circuit includes a plurality of control devices corresponding to the switch devices, and is configured to sequentially activate one of the switch devices during a test procedure of the testing apparatus. The detection circuit is configured to provide a first power supply voltage to a first terminal of each switch device, and to selectively provide a second power supply voltage to a second terminal of each switch device deactivated by the control circuit based on a selection signal from the control device corresponding to each switch device.

The methods and features of the present disclosure have been sufficiently described in the provided examples and descriptions. It should be understood that any modifications or changes without departing from the spirit of the present disclosure are intended to be covered in the protection scope of the present disclosure.

Moreover, the scope of the present application is not intended to be limited to the particular embodiments of the process, machine, manufacture, and composition of matter, means, methods and steps described in the specification. As those skilled in the art will readily appreciate from the present disclosure, processes, machines, manufacture, composition of matter, means, methods or steps presently existing or later to be developed, that perform substantially the same function or achieve substantially the same result as the corresponding embodiments described herein, can be utilized according to the present disclosure.

Accordingly, the appended claims are intended to include within their scope processes, machines, manufacture, compositions of matter, means, methods or steps. In addition, each claim constitutes a separate embodiment, and the combination of various claims and embodiments are within the scope of the present disclosure.

What is claimed is:

1. A testing apparatus, comprising:
a plurality of devices under test (DUTs); and
an advanced process control monitor (APCM), comprising:
a switch circuit, comprising a plurality of switch devices corresponding to the DUTs;
a control circuit, comprising a plurality of control devices corresponding to the switch devices, and configured to sequentially activate one of the switch devices during a test procedure of the testing apparatus;
a detection circuit, configured to provide a first power supply voltage to a first terminal of each of the plurality of switch devices; and
an auxiliary control circuit, configured to provide a second power supply voltage to a second terminal of each of the plurality of switch devices deactivated by the control circuit.

2. The testing apparatus of claim 1, wherein the first power supply voltage is substantially equal to the second power supply voltage.

3. The testing apparatus of claim 1, wherein the second power supply voltage is higher than the first power supply voltage to compensate a voltage drop caused by a routing path from the auxiliary control circuit to each deactivated switch device.

4. The testing apparatus of claim 1, wherein each of the control devices comprises a D flip-flop, and the control devices are connected in series.

5. The testing apparatus of claim 4, wherein when the test procedure of the testing apparatus starts, an input data signal is delivered through the control devices every clock cycle of a clock signal to sequentially activate one of the switch devices.

6. The testing apparatus of claim 5, wherein upon the input data signal is delivered to a last one of the control devices, a report voltage signal is asserted.

7. The testing apparatus of claim 1, wherein each of the switch devices comprises a P-type transistor.

8. The testing apparatus of claim 7, wherein the P-type transistor comprises a gate terminal, electrically connected to a respective selection signal generated by the corresponding control device: the first terminal, electrically connected to the first power supply voltage: the second terminal, selectively connected to the second power supply voltage or a terminal of the corresponding DUT based on the respective selection signal; and a bulk terminal, electrically connected to the first power supply voltage.

9. The testing apparatus of claim 8, wherein the first terminal and the second terminal are a source terminal and a drain terminal, respectively.

10. The testing apparatus of claim 9, wherein the source terminal and the drain terminal are P-type doped regions formed on a carrier.

11. The testing apparatus of claim 10, wherein the carrier is an N-type substrate or an N-type well formed on a P-type substrate.

12. The testing apparatus of claim 1, wherein the DUTs comprises a first portion and a second portion, and each DUT in the second portion is a dummy device having a particular feature.

13. The testing apparatus of claim 12, wherein the particular feature of each DUT in the second portion forms a particular feature pattern.

14. A method, comprising:
providing a testing apparatus including a plurality of switch devices and a plurality of devices under test (DUTs);
sequentially activating each of the switch devices of the testing apparatus to test the respective DUT; and
in response to a specific switch device not being activated, applying a first power supply voltage and a second power supply voltage to a first terminal and a second terminal of the specific switch device, respectively.

15. The method of claim 14, wherein the first power supply voltage is substantially equal to the second power supply voltage.

16. The method of claim 15, further comprising:
in response to the specific switch device being activated, applying the first power supply voltage and a voltage from the DUT corresponding to the specific switch device to the first terminal and the second terminal of the specific switch device, respectively.

17. The method of claim 14, wherein each of the switch devices comprises a P-type transistor.

18. A testing apparatus, comprising:
a plurality of devices under test (DUTs); and
an advanced process control monitor (APCM), comprising:
a switch circuit, comprising a plurality of switch devices corresponding to the DUTs;
a control circuit, comprising a plurality of control devices corresponding to the switch devices, and configured to sequentially activate one of the switch devices during a test procedure of the testing apparatus; and
a detection circuit, configured to provide a first power supply voltage to a first terminal of each switch device, and to selectively provide a second power supply voltage to a second terminal of each switch device deactivated by the control circuit based on a selection signal from the control device corresponding to each switch device.

19. The testing apparatus of claim 18, wherein the first power supply voltage is substantially equal to the second power supply voltage.

20. The testing apparatus of claim 19, wherein each of the switch devices comprises a P-type transistor having a gate terminal, electrically connected to the selection signal from the control device corresponding to each switch device; the first terminal, electrically connected to the first power supply voltage; the second terminal, selectively connected to the second power supply voltage or a terminal of the corresponding DUT based on the respective selection signal; and a bulk terminal, electrically connected to the first power supply voltage.
